(19) United States
(12) Patent Application Publication
(10) Pub. No.: US 2025/0239551 A1
(43) Pub. Date: Jul. 24, 2025

(54) ELECTRONIC COMPONENT COMPRISING CONNECTION PILLARS

(71) Applicant: STMicroelectronics International N.V., Geneva (CH)

(72) Inventor: Mohamed BOUFNICHEL, MONNAIE (FR)

(21) Appl. No.: 19/010,806

(22) Filed: Jan. 6, 2025

(30) Foreign Application Priority Data
Jan. 19, 2024 (FR) FR2400536

(51) Int. Cl. H01L 23/00

(52) U.S. Cl. CPC H01L 24/05; H01L 24/03; H01L 24/11; H01L 24/13; H01L 2224/02317; H01L 2224/0235; H01L 2224/0401; H01L 2224/05548; H01L 2224/05558; H01L 2224/05567; H01L 2224/1147; H01L 2224/13008; H01L 2224/13014; H01L 2224/13024

(57) ABSTRACT

An electronic components comprising electronic pillars is provided. An example electronic component, such as an electronic chip, comprising a semiconductor substrate having opposite first and second faces and electrically-conductive pillars intended to be connected to an element external to the electronic component, an insulating layer covering the second surface of the substrate, a first portion of the electrically-conductive pillars projecting from the insulating layer, and a second portion of the electrically-conductive pillars crossing the insulating layer and extending in the semiconductor substrate down to a depth smaller than the thickness of the semiconductor substrate.

### CROSS REFERENCE TO RELATED APPLICATIONS

This application claims the priority benefit of French patent application number 2400536, filed on Jan. 19, 2024, entitled “Composant électronique comprenant des piliers de connexion”, which is hereby incorporated by reference to the maximum extent allowable by law.

### TECHNICAL FIELD

The present disclosure concerns the field of electronic components having electric connection pillars, and more particularly electronic chips having electric connection pillars to be connected to a housing or to another electronic chip.

### BACKGROUND

To connect an electronic chip to an external element, connection balls or pillars may be provided on a surface of the electronic chip and connected to conductive tracks of the electronic chip. Thus, it is possible to place into contact the connection balls or pillars with conductive areas or tracks located on an external element, for example a housing or another electronic chip.

The decrease in the size of electronic chips goes along with the decrease in the size of these connection elements. The use of pillars is preferred to the use of balls to have a high aspect ratio, the aspect ratio being the ratio of the height to the diameter of the connection pad.

However, the use of connection pillars, particularly when they have a high aspect ratio and/or when they have small dimensions, may have certain disadvantages: the brittleness of the connection pillars, the high duration and cost of the connection pillar manufacturing method, or the risk of tearing of the connection pillars away from the surface of the electronic chip on which they are formed.

### BRIEF SUMMARY

There exists a need to at least partly improve certain aspects of electronic chips comprising connection pillars.

This object is achieved by an electronic component, such as an electronic chip, comprising a semiconductor substrate having opposite first and second surfaces and electrically-conductive pillars, intended to be connected to an element external to the electronic component, an insulating layer covering the second surface of the substrate, a first portion of the electrically-conductive pillars projecting from the insulating layer and a second portion of the electrically-conductive pillars crossing the insulating layer and extending in the semiconductor substrate down to a depth smaller than the thickness of the semiconductor substrate.

According to an embodiment, the second portion of the electrically-conductive pillars is formed by one or a plurality of cylindrical elements.

According to an embodiment, the second portion of the electrically-conductive pillars is formed of a plurality of coaxially-arranged tubular elements.

According to an embodiment, it comprises an electrically-insulating layer arranged between the second portion of the electrically-conductive pillars and the semiconductor substrate.

According to an embodiment, it comprises an interface layer, preferably made of TiCu, in contact with the second portion of the electrically-conductive pillars, the interface layer being arranged between the electrically-conductive pillars and the electrically-insulating layer.

According to an embodiment, it comprises an active area extending in the semiconductor substrate from the second surface and containing at least one discrete electronic component, each electrically-conductive pillar further comprising a connection track extending over the second surface of the semiconductor substrate and electrically-connected to the active area.

According to an embodiment, the first portion of the electrically-conductive pillars has a height greater than 25 μm.

According to an embodiment, the second portion of the electrically-conductive pillars has a height of at least 5 μm.

This object is also achieved by a method of manufacturing an electronic component, such as an electronic chip, comprising a semiconductor substrate having opposite first and second surfaces and electrically-conductive pillars, intended to be connected to an element external to the electronic component, the method comprising the following steps:
forming an electrically-insulating layer on the second surface of the semiconductor substrate,
forming openings crossing the insulating layer and continuing across part of the thickness of the semiconductor substrate,
forming the first portion of the electrically-conductive pillars by filling the openings with an electrically-conductive material,
forming the second portion of the electrically-conductive pillars from the first portion of the pillars.

According to an embodiment, it comprises, before the filling of the openings with the electrically-conductive material, a step of forming of an electrically-insulating layer in the openings.

According to an embodiment, it comprises, between the step of forming of an electrically-insulating layer and the step of filling of the openings with the electrically-conductive material, a step of deposition of an interface layer, preferably made of TiCu, into the openings.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial and simplified cross-section view of an example of an electronic chip;

FIG. 2 is a partial and simplified cross-section view of an electronic chip;

FIG. 3 is a partial and simplified cross-section view of a pillar positioned in a substrate according to a specific embodiment of an electronic chip;

FIG. 4, FIG. 5, and FIG. 6 are simplified top and cross-section views of different pillars positioned in a substrate according to a specific embodiment of an electronic chip (the dotted lines show the delimitation of the electronic chips formed in the substrate);

FIG. 7A, FIG. 7B, FIG. 7C, FIG. 7D, FIG. 7E, FIG. 7F, FIG. 7G, and FIG. 7H each are a partial and simplified cross-section view of a structure obtained at different steps of an embodiment of a method of manufacturing the microchip of FIG. 2.

The various elements of the drawings are not shown at a uniform scale for a better readability of the drawings.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless otherwise specified, the expressions “about”, “approximately”, “substantially”, and “in the order of” mean to within 10%, preferably to within 5%. Further, it is here considered that the terms “insulating” and “conductive” respectively mean “electrically insulating” and “electrically conductive”.

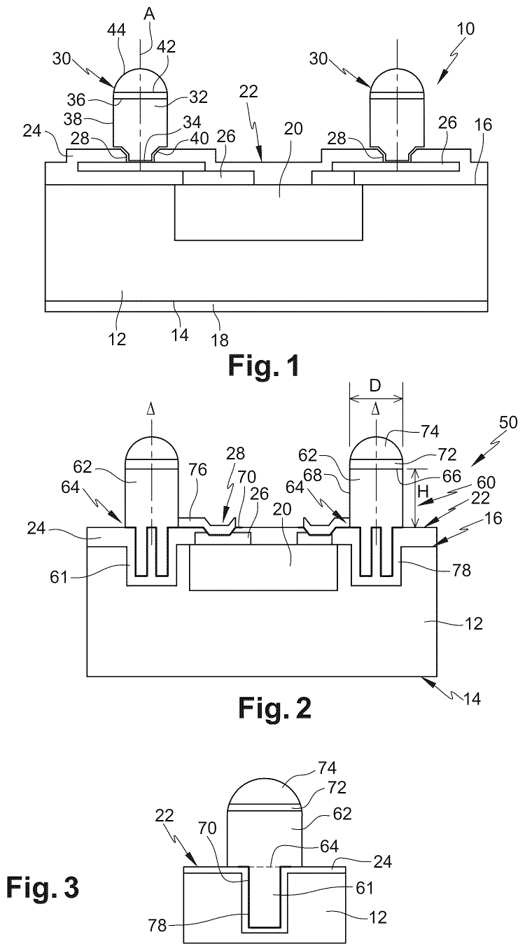

FIG. 1 is a partial and simplified cross-section view of an example of an electronic chip 10.

Electronic chip 10 comprises:
a semiconductor substrate 12 comprising a lower surface 14 (first surface) and an upper surface 16 (second surface);
an insulating layer 18 capable of covering lower surface 14;
an active area 20 in substrate 12 flush with upper surface 16, one or a plurality of electronic components, not shown, being formed inside and/or on top of active area 20;
an interconnection structure 22 covering the upper surface 16 of the substrate, interconnection structure 22 comprising an upper surface and a lower surface in contact with substrate 12, the interconnection structure comprising an insulating layer 24 and conductive tracks 26 in insulating layer 24, some of conductive tracks 26 being in contact with active area 20;
openings 28 in insulating layer 24, each exposing a portion of one of conductive tracks 26; and
connection pillars 30, two connection pillars being shown as an example in FIG. 1, each pillar being connected to one of conductive tracks 26.

Each connection pillar 30 comprises a shaft 32 extending along an axis A substantially orthogonal to upper surface 16. Shaft 32 comprises a base 34 on the side closest to substrate 12, an end surface 36 opposite to base 34 on the side most distant from substrate 12, and a side wall 38 coupling base 34 to end surface 36. Connection pillar 30 further comprises an interface layer 40 interposed between base 34 and interconnection structure 22. Pillar 30 further comprises a finish layer 42 covering end surface 36 and a block 44 of a bonding material covering finish layer 42.

The use of connection pillars 30 such as shown in FIG. 1 may have certain disadvantages. Connection pillars 30 may be brittle when they have small dimensions or when they have a high aspect ratio (also called form factor). Further, each connection pillar 30 is mechanically coupled to interconnection structure 22 only by interface layer 34.

Further, during the manufacturing of such a device, the method comprises a step during which interface layer 40, deposited over the entire wafer, is etched after the forming of connection pillar 30 thereon. Now, when the material is being etched, the etching extends laterally under the conductive material of connection pillars 30 (phenomenon called ‘undercut’), which cause a partial etching of the interface layer 34 located under pillar 30, from its periphery. This embrittles the coupling between shaft 32 and interconnection structure 22. An increase in the risk of tearing of connection pillar 30 away from connection structure 22 can then be observed. The percentage of contact surface area lost increases as the pillar diameter decreases.

FIG. 2 is a partial and simplified cross-section view of an example of an electronic chip 50. Electronic chip 50 comprises all the elements of the electronic chip 10 of FIG. 1, with the difference that connection pillars 30 are replaced with connection pillars 60.

Each connection pillar 60 comprises two portions mechanically fastened to each other:
a first portion (upper portion of the pillar) arranged to project from chip 50, to allow an electric connection with an external element (such as a housing or another electronic chip), the first portion extending or projecting from the upper surface of the insulating layer 24 of the interconnection structure 22 covering the second surface 16 of substrate 12,
a second portion (lower portion of the pillar) which thoroughly crosses the insulating layer 24 of interconnection structure 22 and a portion of substrate 12, the height of the second portion being lower than the thickness of substrate 12.

More particularly, the first portion of the pillar comprises a shaft 62 which extends along an axis Δ substantially orthogonal to upper surface 16 and to the lower surface of the substrate, the shaft projecting out of the insulating layer 24 of interconnection structure 22 positioned on the upper surface 16 of substrate 12, shaft 62 having a base 64 arranged at the upper surface level of interconnection structure 24, an end surface 66, positioned outside of substrate 12, and opposite to base 64, and a side wall 68 connecting base 64 to end surface 66.

A finish layer 72 covers end surface 66 and is in direct physical contact with end surface 66.

A block 74 of a bonding material covers finish layer 72.

The base 64 of the first portion of the pillar is in direct contact with the second portion of the pillar.

The first portion is visible, it projects from the substrate. The second portion is buried within the component: it is not visible during a normal use of electronic component 50. Only a cutting of component 50 may enable to observe it.

The second portion of the pillar may be formed by one or a plurality of elements 61. These elements are in direct contact with the base 64 of the shaft 62 of the first portion of pillar 60.

Elements 61 comprise a base (or lower surface), a side wall, and an upper face. The upper surface is in direct contact with the upper portion of the pillar.

Elements 61 may have different shapes and/or different dimensions. The shapes and/or dimensions may be identical or different within a same pillar or between different pillars.

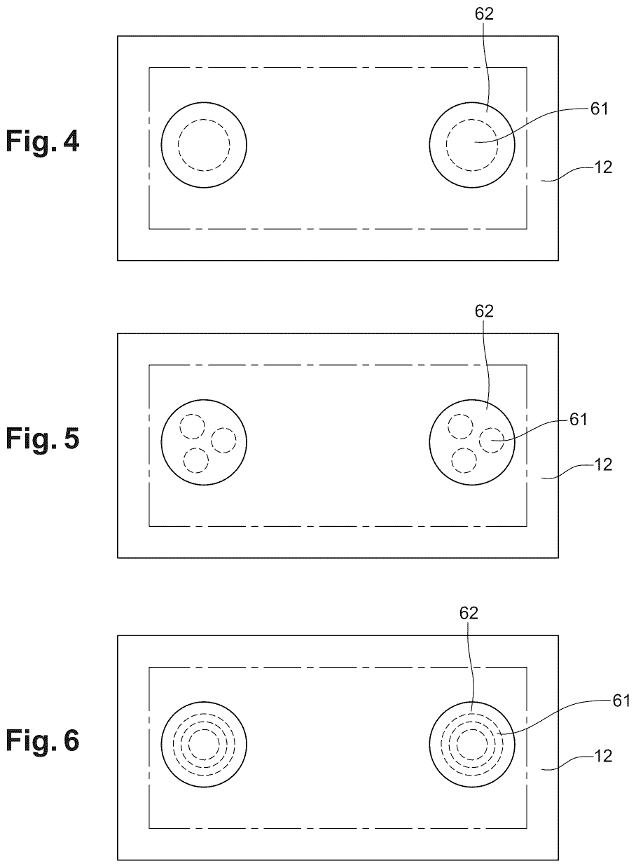

According to different embodiments, the second portion of pillar 60 may comprise a single element 61 (FIGS. 3, 4) or a plurality of elements 61 (FIGS. 2, 5, and 6).

According to different embodiments, the second portion may be formed by one cylindrical element 61 (FIGS. 3 and 4) or by a plurality of cylindrical elements 61 (FIGS. 2, 5). The second portion of pillar 60 may also be formed of one or a plurality of tubular elements 61. The tubular elements may be coaxially arranged (FIG. 6).

The cross-section area of an element 61 or the sum of the cross-section areas of elements 61 is preferably smaller than the cross-section area of shaft 62.

Elements 61 preferably have a height in the range from 5 μm to 50 μm. They for example have a 10-μm height. The average diameter of elements 61 is preferably in the range from 1 μm to 40 μm. The average diameter of a cylindrical element is, for example, 5 μm.

By average diameter, there is meant the diameter of an element 61 with a circular base having the same surface area as element 61.

Each pillar 60 is anchored in substrate 12 across a portion of the thickness of substrate 12 due to the element 61 or to the elements 61 of the second portion of pillar 60. The mechanical stability of pillar 60 is improved with respect to the mechanical stability of a pillar 30 such as that shown in FIG. 1. The risk of tearing of connection pillar 60 away is considerably decreased.

Electronic chip 50 further comprises an interface layer 70 covering the base and the side wall of elements 61 (that is, it fully covers elements 61 except for the upper surface in contact with the base 64 of shaft 62).

This interface layer 70 plays the role of a seed layer during the forming of elements 61.

Since interface layer 70 covers element(s) 61, it thus has a developed surface area larger than the surface area of interface layer 40 in contact with the base 34 of the pillar 30 of the component shown in FIG. 1.

Thus, the influence of the undercut of interface layer 70 under the shaft 62 of pillars 60 is considerably decreased, even for pillars of small dimensions (typically with its shaft 62 having an average diameter smaller than 50 μm, or even smaller than or equal to 25 μm, or even smaller than or equal to 15 μm).

As an example, for a pillar 30, as shown in FIG. 1, having a shaft 32 with a 15-μm average diameter and for an interface layer 40 having a 0.3-μm thickness, the percentage of contact surface area lost between pillar 30 and interface layer 40, due to undercut, would be approximately 23%.

As a non-limiting illustration, for a pillar 60, such as shown in FIG. 2, having a shaft 62 with 15-μm average diameter and for an interface layer 70 having a 0.3-μm thickness, the percentage of contact surface area lost between pillar 60 and interface layer 70, due to undercut, would only be approximately 8%, 5%, and 3% if the pillar comprises, respectively, one element 61, two elements 61, and three elements 61, each element 61 having a 5-μm diameter and a 10-μm height.

An insulating layer 78 is arranged between interface layer 70 and substrate 12 to insulate substrate 12 from pillars 60.

Further, the component comprises a connection track 76 (or RDL for ‘Redistribution layer’) on interconnection structure 22 and connecting the shaft 62 of pillar 60 to one of conductive tracks 26 in one of openings 28.

An interface layer 70 is also present between connection track 76 and interconnection structure 22.

This interface layer 70 also plays the role of a seed layer during the forming of connection track 76.

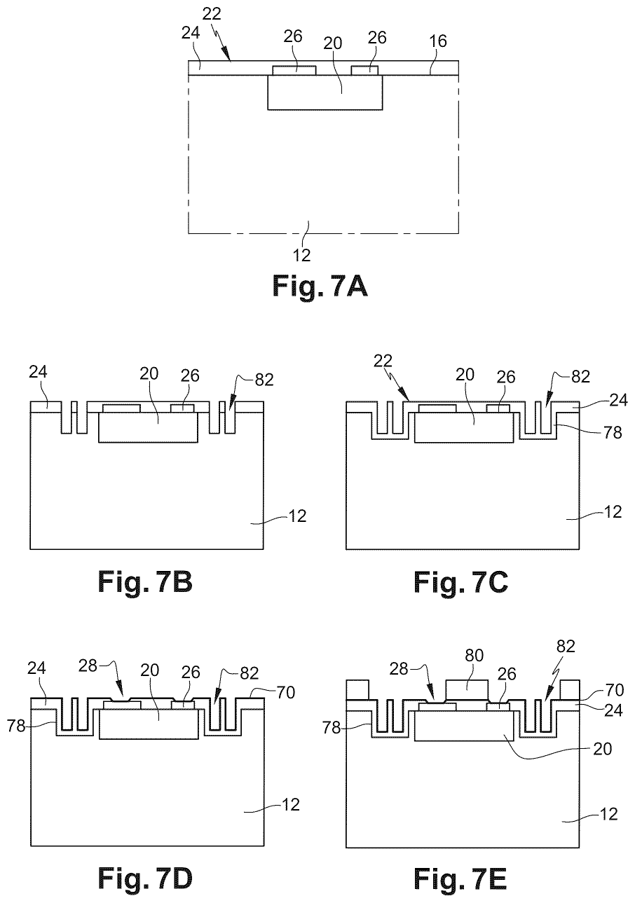

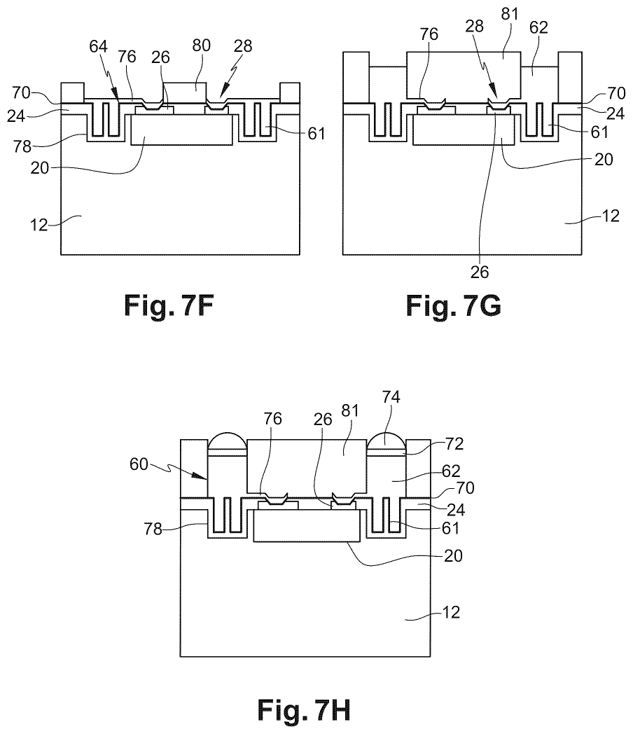

The method of manufacturing such an electronic chip 50, shown in FIG. 2, will now be described, referring to FIGS. 7A to 7H.

The method comprises at least the following steps:
providing a structure comprising a substrate 12 in which an active area 20 has been formed, conductive tracks 26 being positioned in substrate 12 or on the upper surface of substrate 12 and being connected to active area 20,
covering the upper surface 16 of substrate 12 with an insulating layer 24,
forming openings 82 crossing insulating layer 24 and extending across part of the thickness of semiconductor substrate 12,
forming the first portion of electrically-conductive pillars 60 by filling openings 82 with an electrically-conductive material,
forming the second portion of electrically-conductive pillars 60 from the second portion of the pillars.

More particularly, the method may comprise the following steps:
a) forming an insulating layer 24 over a structure comprising a substrate 12 in which an active area 20 has been formed, conductive tracks 26 being positioned in substrate 12 or on the upper surface of the substrate 12 and being connected to active area 20, insulating layer 24 covering conductive tracks 26 and the upper surface 16 of substrate 12 (FIG. 7A),
b) forming one or a plurality of openings 82 at the desired location of each element 61 of connection pillar 60, the openings crossing insulating layer 24 and extending in substrate 12 (FIG. 7B),
c) forming an insulating layer 78 in openings 82 to insulate substrate 12 from the second portion of the pillars (FIG. 7C),
d) forming openings 28 in insulating layer 24 to make conductive tracks 26 accessible,
e) covering the obtained structure with an interface layer 70 (FIG. 7D),
f) locally depositing protective films 80 over the structure to delimit the areas on which the conductive material is to be deposited and to protect the other areas (FIG. 7E),
g) depositing a conductive material to form the element(s) 61 of the second portion of pillar 60, and then to form connection elements 76 (FIG. 7F),
h) locally depositing protective films 81 over the structure obtained at step f) to delimit the areas on which the conductive material of the shaft 62 of pillars 60 is to be deposited and to protect the other areas,
i) growing the shafts 62 of pillars 60 from elements 61 (FIG. 7G),
j) forming, on the end surface 66 of the shaft 62 of pillar 60, finish layer 72, and block 74 of bonding material (FIG. 7H),
k) removing protective films 81,
l) etching interface layer 70 to electrically insulate pillars 60 from one another.

During step a), one or a plurality of discrete components, not shown, have been formed inside and/or on top of active area 20. The discrete component(s) are, for example, selected from among transistors, diodes, thyristors, triacs, filters, etc.

According to an embodiment, at this stage of the procedure, substrate 12 corresponds to a plate.

Substrate 12 is made, for example, of silicon (Si), of silicon carbide (SiC), of a III-V compound, in particular of gallium nitride (GaN), or of a II-VI compound. Substrate 12 may have a monolayer or multilayer structure, for example, a structure of silicon-on-insulator (SOI) type. As an example, substrate 12 may comprise a GaN layer covering a silicon support. According to an embodiment, the thickness of substrate 12 is in the range from 50 μm to 300 μm.

A single active area is shown in the drawings, but the active areas 20 of a plurality of microchips may be formed inside and/or on top of substrate 12, and active areas 20 may be identical or different.

In FIG. 7A, interconnection structure 22 comprises two conductive tracks 26 connected to active area 20 and an insulating layer 24 covering conductive tracks 26 and the upper surface 16 of substrate 12 around conductive tracks 26.

More than two conductive tracks 26 may be connected to active area 20.

Conductive tracks 26 are, for example, made of materials selected from among copper, a copper alloy, titanium, a titanium alloy, titanium nitride, platinum, and a platinum alloy. It may also be aluminum. According to an embodiment, the thickness of each metal track 26 is in the range from 0.5 μm to 1.5 μm.

Insulating layer 24 may be a multilayer formed of a plurality of insulating layers.

Insulating layer 24 may be made of a dielectric material, such as an oxide or a nitride, and it preferably is a silicon oxide (SiO2), a silicon nitride (for example Si3N4), a silicon oxynitride (for example SiOxNy), or a hafnium oxide (HfO2). Insulating layer 24 may also be made of a polymer material.

According to an embodiment, the thickness of insulating layer 24 is in the range from 0.5 μm to 1.5 μm.

FIG. 7B shows the structure obtained after the forming of an opening 82 at the desired location of each element 61 of connection pillar 60 (step b)). Openings 82 thoroughly cross interconnection structure 22 and extend over part of the thickness of substrate 12 from upper surface 16. The openings are blind holes (in other words the openings do not thoroughly cross substrate 12). The depth of openings 82 may be in the range from 5 μm to 50 μm.

One or a plurality of openings 82 are formed for each pillar in order to form, respectively, one or a plurality of elements 61.

In the drawings, openings 82 have a circular cross-section. However, openings 82 could have a square cross-section, a rectangular cross-section, or a rectangular cross-section with rounded corners.

Openings 82 may be formed by laser etching.

Preferably, openings 82 are formed by deep reactive ion etching (DRIE) steps.

To form openings 82, a mask may be used. Layer 24 is etched through the openings of the mask across its entire thickness. Then, openings 82 are continued across part of the thickness of substrate 12. The mask may be a resin mask. An insulating layer 24, for example made of oxide, may play the role of a ‘hard mask’ during the forming of openings 82 in substrate 12.

During step c), insulating layer 78 is formed in each opening. FIG. 7C shows the obtained structure.

Insulating layer 78 covers the side walls and the bottom of opening 82. Insulating layer 78 may be formed by deposition of an insulating layer into openings 82 or by oxidizing of substrate 12. For example, this step may be carried out by thermal oxidation, low thermal oxidation, by wet oxidation, by plasma-enhanced chemical vapor deposition (PECVD). FIG. 7C shows the embodiment for which insulating layer is obtained by oxidation of substrate 12. The thickness of the insulating layer is selected so as not to close openings 82. It is, for example, in the range from 100 nm to 1 μm.

For each connection pillar 60 to be formed, an opening 28 is made in insulating layer 24 to expose one of conductive tracks 26 (step d). These openings 28 may be formed by using a mask.

During step e), an interface layer 70 is formed. At this stage of the method, interface layer 70 covers all the walls of cavities 82, in particular the side walls and the bottom of cavities 82, the walls of opening 28, and the exposed portion of insulating layer 24 connecting cavity 82 to the corresponding opening 28.

The thickness of interface layer 70 is in the range from 10 nm to 1 μm. Interface layer 70 plays the role of a seed for the forming of pillar 60 and of the connection track 76 of connection pillar 60. Interface layer 70 may comprise a titanium or chromium layer, playing the role of a bonding layer, and a layer of copper playing the role of a seed layer for the subsequent forming of shaft 62 and of connection track 76. Interface layer 70 is preferably made of TiCu.

During step f), protective films 80 are deposited on the structure. They play the role of a mask during the forming of the pillars, pillars 60 being formed in the openings of the mask.

During step g), the element(s) 61 of the second portion of the pillars are formed, as well as tracks 76 (FIG. 7F).

For each connection pillar 60 to be formed, each cavity 82 is completely filled with a conductive material, thus forming the elements 61 of connection pillars 60. When cavities 82 are filled, the connection portion 76 of each connection pillar is formed.

The conductive material forming elements 61 may be deposited on interface layer 70 by plasma-enhanced chemical vapor deposition (PECVD) or by atomic layer deposition (ALD).

Preferably, the conductive material of elements 61 is deposited by ALD. The ALD technique is particularly advantageous to fill openings of small dimensions and/or having a high form factor, that is, when the ratio of the cavity height to the cavity diameter is high. In this case, the deposition of the conductive material is performed from interface layer 70 in a direction substantially perpendicular to interface layer 70. The deposition of the conductive material is particularly performed from the side walls of cavity 82.

The conductive material forming connection tracks 76 may be deposited on interface layer 70 by electrodeposition. The growth takes place from interface layer 70.

The thickness of the interface layer is, for example, in the range from 0.3 to 0.9 μm.

At step h), protective films 81 are locally formed on the structure obtained at step g).

Step h) may be preceded by the removal of the protective films 80 deposited at step f), or the protective films 81 of step h) may be deposited over the films 80 applied at step f) in order to cover them.

The protective films 80 formed at step f) and/or the protective films 81 formed at step h) are, for example, resins. They can be removed by wet etching (‘stripping’).

Protective film 81 comprises openings vertically in line with the positions of the shafts 62 of pillars 60 which will be deposited at step G).

The growth of the first portion of pillars 60 is preferably performed by electrodeposition. The conductive material forming shaft 62 is deposited from the second portion of pillars 60. The growth occurs in a direction substantially perpendicular to the main surfaces 14 and 16 of substrate 12 (FIG. 7G).

To form shaft 62, the conductive material thus can be deposited substantially over a thickness equal to half the average diameter of elements 61. Once formed, shaft 62 protrudes from the upper surface 16 of substrate 12.

Shaft 62 may have a substantially cylindrical shape having an axis Δ with a circular, square, rectangular, etc. base. The average diameter D of shaft 62 of the pillar 60 is in the range from 10 μm to 150 μm. According to an embodiment, end surface 66 is substantially perpendicular to axis Δ.

The total height H of shaft 62 from base 64 to end surface 66 is, for example, in the range from 75 μm to 400 μm. The height of shaft 62 projecting from insulating layer 24 is in the range from 25 μm to 100 μm. The aspect ratio of shaft 62, which corresponds to the ratio of the total height H of shaft 62 to the average diameter D of shaft 62, is in the range from 0.5 to 40.

Shaft 62, elements 61, and connection track 76 are preferably made of a same material. Shaft 62, elements 61, and connection track 76 are made of metal, for example of copper, of nickel, of silver, of gold, or of an alloy of these metals. Preferably, they are made of copper.

At step H), for each connection pillar 60, a finish layer 72 and block 74 of bonding material are formed on end surface 66.

The thickness of finish layer 72 is in the range from 10 nm to 5 μm, for example 3 μm. Finish layer 72 is made of a conductive material which improves the bonding of block 74. Finish layer 72 is for example made of metal, particularly gold, silver, platinum, palladium, nickel, titanium, chromium, and/or tantalum. Preferably, it is made of nickel. Such a layer may be deposited by physical vapor deposition (PVD). Finish layer 72 further enables to avoid an oxidation of the end surface 66 of shaft 62 in the case where the assembly method is not carried out under a neutral or reducing atmosphere.

The material forming block 74 particularly depends on the assembly method implemented for the bonding of electronic chip 50 to another element. The assembly method may in particular comprise a welding step or a sintering step.

The material forming block 74 is, for example, a solder material. It may be tin, silver, or one of their alloys, for example SnAgCu, SnAg, or also SnAgPb. It may also be a material based on gold (such as SnAu or SnAuCu), based on a palladium (such as SnPd or SnPdCu), or based on platinum (such as SnPt or SnPtCu).

The height of block 74, measured from finish layer 72, may be approximately 25 μm.

After the removal of protective films 80 (step F)), the interface layer 70 positioned between the pillars, and more particularly between connection tracks 76, is removed, preferably by etching (step l)). The removal may be carried out by wet etching. The etching solution may be a hydrofluoric acid (HF) solution or an ammonia solution. The etching solution will be selected according to the nature of the passivation layer 24 (oxide or polymer, for example).

The method may further comprise a cutting step to separate the different electronic chips 50 formed in the same substrate 12.

At the end of the method, a chip such as shown in FIG. 2 is obtained.

Each electronic chip 50 thus individualized can then be bonded to an external element, for example, a package or another electronic chip.

Such electronic chips find applications in many industrial fields, and in particular in the automobile field or the telephony field.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic component comprising:
a semiconductor substrate having a first surface opposite a second surface and electrically-conductive pillars configured to be connected to an element external to the electronic component;
an insulating layer covering the second surface of the substrate;
wherein a first portion of the electrically-conductive pillars project from the insulating layer and a second portion of the electrically-conductive pillars cross the insulating layer and extend in the semiconductor substrate down to a depth smaller than a thickness of the semiconductor substrate.

2. The electronic component of claim 1, wherein the second portion of the electrically-conductive pillars is formed by one or a plurality of cylindrical elements.

3. The electronic component of claim 1, wherein the second portion of the electrically-conductive pillars is formed of a plurality of coaxially-arranged tubular elements.

4. The electronic component of claim 1, comprising an electrically-insulating layer arranged between the second portion of the electrically-conductive pillars and the semiconductor substrate.

5. The electronic component of claim 1, comprising an interface layer in contact with the second portion of the electrically-conductive pillars, the interface layer being arranged between the electrically-conductive pillars and an electrically-insulating layer.

6. The electronic component of claim 1, comprising an active area extending in the semiconductor substrate from the second surface and containing at least one discrete electronic component, each electrically-conductive pillar further comprising a connection track extending over the second surface of the semiconductor substrate and electrically-connected to the active area.

7. The electronic component of claim 1, wherein the first portion of the electrically-conductive pillars has a height greater than 25 μm.

8. The electronic component of claim 1, wherein the second portion of the electrically-conductive pillars has a height of at least 5 μm.

9. A method of manufacturing an electronic component comprising a semiconductor substrate having a first surface opposite a second surface and electrically-conductive pillars configured to be connected to an element external to the electronic component, the method comprising:
forming an electrically-insulating layer on the second surface of the semiconductor substrate;
forming openings crossing the electrically-insulating layer and continuing across part of a thickness of the semiconductor substrate;
forming a first portion of the electrically-conductive pillars by filling the openings with an electrically-conductive material;
forming a second portion of the electrically-conductive pillars from the first portion of the pillars.

10. The method of claim 9 further comprising, before the filling of the openings with the electrically-conductive material, forming of an electrically-insulating layer in the openings.

11. The method of claim 10 further comprising, between forming an electrically-insulating layer and filling the openings with the electrically-conductive material, depositing an interface layer into the openings.

12. The method of claim 11, wherein the interface layer comprises TiCu.
